(19) United States
(12) Patent Application Publication
(10) Pub. No.: US 2016/0229692 A1
(43) Pub. Date: Aug. 11, 2016

(54) SEMICONDUCTOR STRUCTURE AND METHOD FOR MANUFACTURING THE SAME

(71) Applicant: UNITED MICROELECTRONICS CORP., Hsinchu (TW)

(72) Inventors: Yuan-Sheng Lin, Bade City (TW); Chang-Sheng Hsu, Hsinchu City (TW); Meng-Jia Lin, Changhua County (TW); Shih-Wei Li, Taoyuan City (TW); Yan-Da Chen, Taipei City (TW)

(21) Appl. No.: 14/643,183

(22) Filed: Mar. 10, 2015

(30) Foreign Application Priority Data
Feb. 6, 2015 (CN) 201510062509.3

(51) Int. Cl. B81C 1/00; B81B 3/00

(52) U.S. Cl. CPC B81C 1/00158; B81B 3/0021; B81B 2203/0127

(57) ABSTRACT

A semiconductor structure and a method for manufacturing the same are provided. The semiconductor structure comprises a base substrate and a MEMS structure. The base substrate comprises a CMOS structure. The MEMS structure is formed on the base substrate adjacent to the CMOS structure. The MEMS structure is connected to the CMOS structure. The MEMS structure comprises a membrane and a backplate. The base substrate has a cavity corresponding to the MEMS structure.

This application claims the benefit of People's Republic of China application Serial No. 201510062509.3, filed Feb. 6, 2015, the subject matter of which is incorporated herein by reference.

### TECHNICAL FIELD

This disclosure relates to a semiconductor structure and a method for manufacturing the same. More particularly, this disclosure relates to a semiconductor structure comprising a MEMS (microelectromechanical systems) structure and a method for manufacturing the same.

### BACKGROUND

MEMS are small integrated devices or systems combining electrical and mechanical components. The size of MEMS may be from sub micrometer level to the millimeter level. Typically, MEMS may comprise a central unit that processes data (the microprocessor) and several components that interact with the surroundings (such as microsensors). Examples of MEMS applications comprise microphones, ultrasonic detectors, flowmeter, and the like.

### SUMMARY

In this disclosure, a semiconductor structure comprising a MEMS structure and a method for manufacturing the same are provided.

According to some embodiment, a semiconductor structure comprises a base substrate and a MEMS structure. The base substrate comprises a CMOS structure. The MEMS structure is formed on the base substrate adjacent to the CMOS structure. The MEMS structure is connected to the CMOS structure. The MEMS structure comprises a membrane and a backplate. The membrane is made of doped polysilicon. The base substrate has a cavity corresponding to the MEMS structure.

According to some embodiment, a method for manufacturing a semiconductor structure comprises the following steps. First, a base substrate and a temporary substrate are provided. The base substrate comprises a CMOS structure. The temporary substrate comprises a carrier layer, a membrane layer, and a backplate for a MEMS structure. The temporary substrate is bonded with the base substrate. A membrane for the MEMS structure is formed by patterning the membrane layer. The membrane and the backplate are connected to the CMOS structure. Then, a cavity corresponding to the MEMS structure is formed in the base substrate.

### BRIEF DESCRIPTION OF THE DRAWINGS

FIG. 1A-FIG. 1B illustrate a semiconductor structure according to one embodiment.

FIG. 2A-FIG. 2F illustrate a method for manufacturing a semiconductor structure according to one embodiment.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

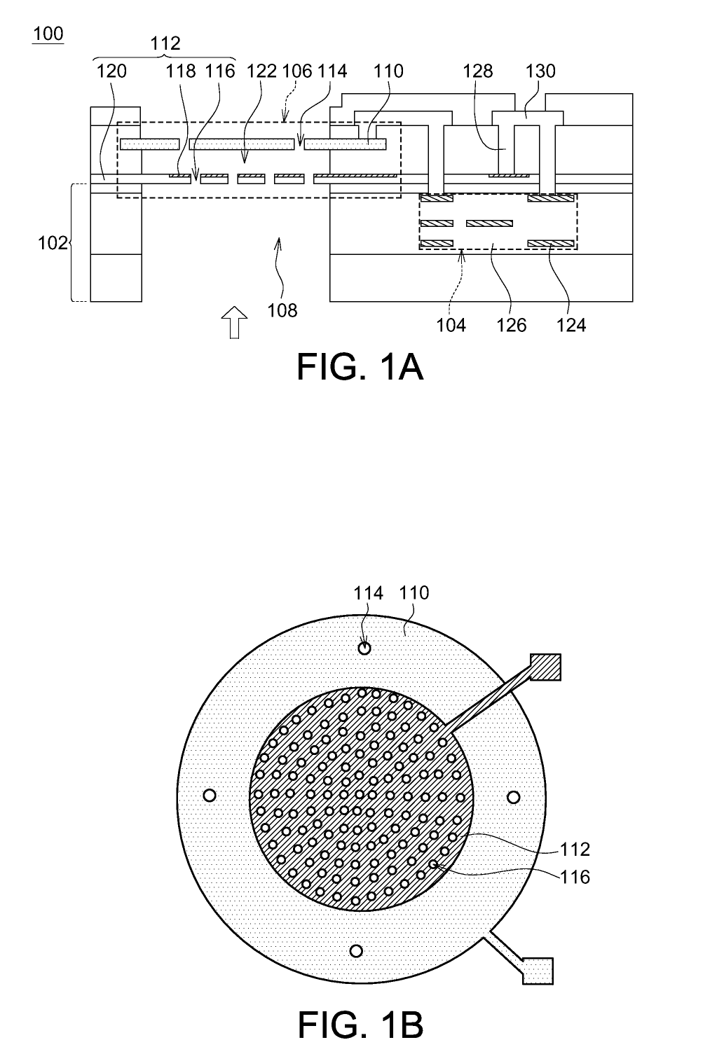

Referring to FIG. 1A-FIG. 1B, a semiconductor structure 100 according to one embodiment is illustrated, wherein FIG. 1B shows a bottom view of a portion of the FIG. 1A (as indicated by the arrow). The semiconductor structure 100 comprises a base substrate 102. The base substrate 102 comprises a CMOS structure 104. The semiconductor structure 100 further comprises a MEMS structure 106. The MEMS structure 106 is formed on the base substrate 102 adjacent to the CMOS structure 104. The MEMS structure 106 is connected to the CMOS structure 104. The MEMS structure 106 comprises a membrane 110 and a backplate 112. The base substrate 102 has a cavity 108 corresponding to the MEMS structure 106.

More specifically, with respect to the MEMS structure 106, the membrane 110 may be made of metal or doped polysilicon, and preferably be made of doped polysilicon for a better performance. The dopant may be phosphorus (for all doped polysilicon in this disclosure). The doping concentration may be adjusted to change the membrane characteristics. The membrane 110 may have a plurality of through holes 114. The backplate 112 may have a plurality of through holes 116 and comprise an electrode layer 118 and a support layer 120 supporting the electrode layer 118. The electrode layer 118 may be made of metal or doped polysilicon. The support layer 120 may be made of nitride. The MEMS structure 106 may further comprises an air gap 122 between the membrane 110 and the backplate 112. While with respect to the CMOS structure 104, it may comprise electrode layers 124 and dielectric layers 126. The CMOS structure 104 is used to control the MEMS structure 106.

The semiconductor structure 100 may further comprise vias 128 and a conductive layer 130 formed above the MEMS structure 106 and the CMOS structure 104. The membrane 110 and the backplate 112 are connected to the CMOS structure 104 by the vias 128 and the conductive layer 130. The vias 128 and the conductive layer 130 may be made of Pt, AlSi, or the like.

Now the description is directed to a method for manufacturing a semiconductor structure according to one embodiment. While the reference numerals are changed, the elements given the same name have features as described above even that the features may not be repeated again.

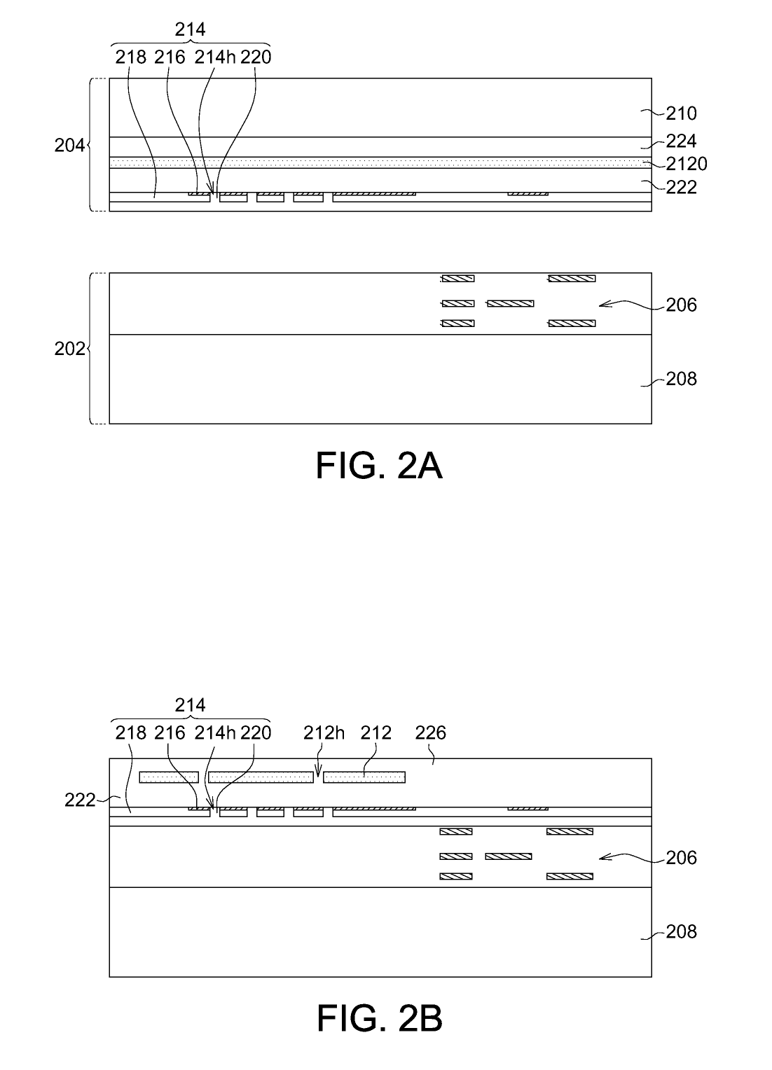

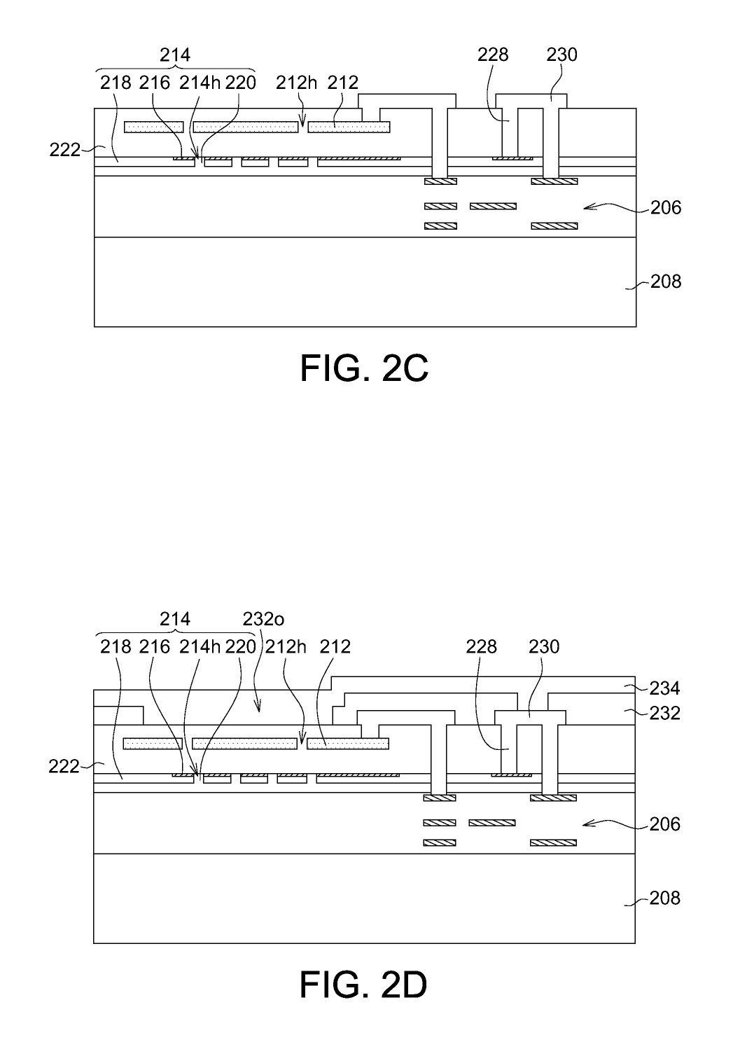

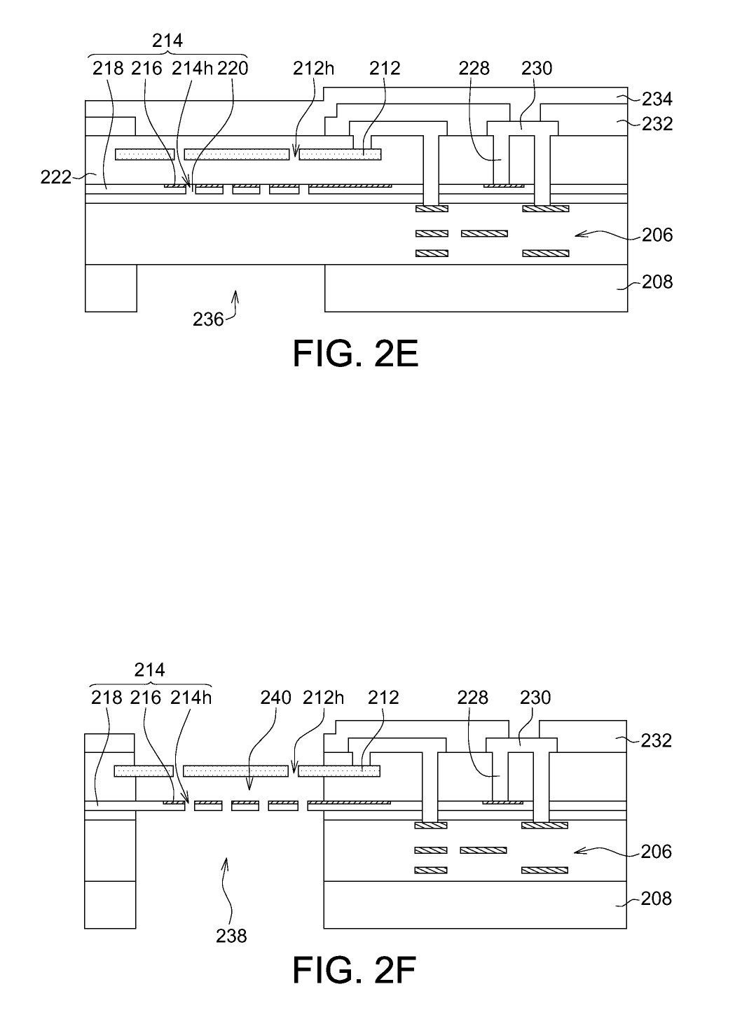

Referring to FIG. 2A, a base substrate 202 and a temporary substrate 204 are provided. The base substrate 202 comprises a CMOS structure 206. The base substrate 202 may further comprise a base 208, such as a wafer. The CMOS structure 206 is formed on the wafer.

The temporary substrate 204 comprises a carrier layer 210, a membrane layer 2120, and a backplate 214 for a MEMS structure. The carrier layer 210 may be a wafer. The membrane layer 2120 may be made of metal or doped polysilicon, and preferably be made of doped polysilicon. The backplate 214 may have a plurality of through holes 214h and comprise an electrode layer 216 and a support layer 218 supporting the electrode layer 216. The electrode layer 216 may be made of metal or doped polysilicon. The support layer 218 may be made of nitride. The backplate 214 may further comprise an oxide 220. The through holes 214h are temperately be plugged up by the oxide 220. The temporary substrate 204 may further comprise a sacrificial layer 222 between the membrane layer 2120 and the backplate 214. The sacrificial layer 222 may be made of oxide. The temporary substrate 204 may further comprise a stop layer 224 between the carrier layer 210 and the membrane layer 2120. The stop layer 224 may be made of oxide.

Referring to FIG. 2B, the temporary substrate 204 is bonded with the base substrate 202. Then, the carrier layer 210 may be removed. Besides, a membrane 212 for the MEMS structure is formed by patterning the membrane layer 2120. The membrane 212 may have a plurality of through holes 212h. In one embodiment, forming the membrane 212 is carried out before bonding the temporary substrate 204 with the base substrate 202 (the case is not shown in the figures). In another embodiment, forming the membrane 212 is carried out after bonding the temporary substrate 204 with the base substrate 202. In this case, after the temporary substrate 204 is bonded with the base substrate 202, the carrier layer 210 and the stop layer 224 are removed. Then, the membrane layer 2120 is patterned to form the membrane 212. Thereafter, a dielectric layer 226 may be formed on the membrane 212. The dielectric layer 226 may be made of oxide.

Referring to FIG. 2C, the membrane 212 and the backplate 214 are connected to the CMOS structure 206. More specifically, the membrane 212 and the backplate 214 may be connected to the CMOS structure 206 by vias 228 and a conductive layer 230 above the MEMS structure and the CMOS structure 206. For the process easiness, the vias 228 and the conductive layer 230 may be made of a conductive material with good etching-resistance, such as Pt or AlSi. The vias 228 and the conductive layer 230 may be formed by a via open process, a metal deposition process and a metal patterning process.

Referring to FIG. 2D, a hard mask layer 232 may be formed on the conductive layer 230. The hard mask layer 232 has an opening 232o corresponding to the MEMS structure. The hard mask layer 232 may be used to protect the made of the CMOS structure 206 in the following etching process and be made of nitride. The hard mask layer 232 may be formed by a deposition process and a patterning process. A protective layer 234 may be further formed over the MEMS structure and the CMOS structure 206. The protective layer 234 may be made of oxide or photo resist. The protective layer 234 may be formed by a deposition process.

Referring to FIG. 2E, the base 208 of the base substrate 202 may be thinned, and an opening 236 may be formed in the base 208. In one embodiment, this step is carried out with the structure upside down. The opening 236 may be formed by deep reactive-ion etching (DRIE).

Referring to FIG. 2F, a cavity 238 corresponding to the MEMS structure is formed in the base substrate 202. More specifically, the cavity 238 may be formed by extending the opening 236, which may be conducted by removing the oxide in the base substrate 202. Besides, an air gap 240 for the MEMS structure may be formed by removing a part of the sacrificial layer 222 (oxide). The oxide 220 plugging up the through holes 214h may also be removed at this step.

By the method described above, the fabrication of the MEMS structure does not have to be constrained by the process for manufacturing the CMOS structure. As such, it is easier to control the membrane stress and the air gap features. Thus, a better performance can be obtained. The semiconductor structure manufactured by said method may be applied in the fields of microphones, ultrasonic detectors, flowmeter, and the like.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, comprising:
a base substrate comprising a CMOS structure; and
a MEMS structure formed on the base substrate adjacent to the CMOS structure, wherein the MEMS structure is connected to the CMOS structure, and the MEMS structure comprises:
a membrane made of doped polysilicon; and
a backplate;
wherein the base substrate has a cavity corresponding to the MEMS structure.

2. The semiconductor structure according to claim 1, wherein the backplate has a plurality of through holes, and the backplate comprises an electrode layer and a support layer supporting the electrode layer.

3. The semiconductor structure according to claim 1, wherein the MEMS structure further comprises:
an air gap between the membrane and the backplate.

4. The semiconductor structure according to claim 1, further comprising:
vias and a conductive layer formed above the MEMS structure and the CMOS structure, wherein the membrane and the backplate are connected to the CMOS structure by the vias and the conductive layer.

5. A method for manufacturing a semiconductor structure, comprising:
providing a base substrate and a temporary substrate, wherein the base substrate comprises a CMOS structure, and the temporary substrate comprises a carrier layer, a membrane layer, and a backplate for a MEMS structure;
bonding the temporary substrate with the base substrate;
forming a membrane for the MEMS structure by patterning the membrane layer;
connecting the membrane and the backplate to the CMOS structure; and
forming a cavity corresponding to the MEMS structure in the base substrate.

6. The method according to claim 5, wherein forming the membrane is carried out before bonding the temporary substrate with the base substrate, and the method further comprises:
after bonding the temporary substrate with the base substrate, removing the carrier layer.

7. The method according to claim 5, wherein forming the membrane is carried out after bonding the temporary substrate with the base substrate, and the method further comprises:
after bonding the temporary substrate with the base substrate and before forming the membrane, removing the carrier layer.

8. The method according to claim 5, wherein the membrane layer is made of doped polysilicon.

9. The method according to claim 5, wherein the backplate has a plurality of through holes, the backplate comprises an electrode layer and a support layer supporting the electrode layer.

10. The method according to claim 9, wherein before forming the cavity, the through holes are plugged up by an oxide, and the oxide is removed at the same step of forming an air gap for the MEMS structure.

11. The method according to claim 5, wherein the temporary substrate further comprises a sacrificial layer between the membrane layer and the backplate, and the method further comprises:
forming an air gap for the MEMS structure by removing a part of the sacrificial layer.

12. The method according to claim 5, wherein the membrane and the backplate are connected to the CMOS structure by vias and a conductive layer above the MEMS structure and the CMOS structure.

13. The method according to claim 12, further comprising:
forming a hard mask layer on the conductive layer, wherein the hard mask layer has an opening corresponding to the MEMS structure.

14. The method according to claim 5, further comprising:
before forming the cavity, forming a protective layer over the MEMS structure and the CMOS structure, thinning a base of the base substrate, and forming an opening in the base, wherein the cavity is formed by extending the opening.
